(19) United States
(12) Patent Application Publication
(10) Pub. No.: US 2014/0027169 A1
(43) Pub. Date: Jan. 30, 2014

(54) ANISOTROPIC CONDUCTIVE FILM

(71) Applicant: BENQ MATERIALS CORPORATION, Taoyuan County (TW)

(72) Inventors: Chien-Huang HUANG, Taichung City (TW); Chen-Kuan KUO, New Taipei City (TW); Lung-Hai WU, Taoyuan County (TW)

(73) Assignee: BENQ MATERIALS CORPORATION, Taoyuan County (TW)

(21) Appl. No.: 13/723,156

(22) Filed: Dec. 20, 2012

(30) Foreign Application Priority Data
Jul. 25, 2012 (TW) 101126951

(51) Int. Cl. H05K 1/09

(52) U.S. Cl. CPC H05K 1/09
USPC 174/268

(57) ABSTRACT

An anisotropic conductive film is disclosed. The anisotropic conductive film includes a substrate, a plurality of insulating resin walls on the substrate and conductive materials. Each insulating resin wall is disposed on the substrate in parallel to each other. The conductive materials are arranged between the insulating resin walls and have conductivity along a direction parallel to the insulating resin walls.

This application claims the benefit of Taiwan application Serial No. 101126951, filed Jul. 25, 2012, the subject matter of which is incorporated herein by reference.

### BACKGROUND OF THE INVENTION

1. Field of the Invention

The invention relates in general to a conductive film, and more particularly to an anisotropic conductive film.

2. Description of the Related Art

As an anisotropic conductive film (ACF) has advantages of one-directional electrical conduction, adhesive and low operating temperature, it has been widely used in a situation that is not suitable for the high temperature lead-tin soldering process, such as, tape automated bonding (TAB), chip on glass (COG) bonding or chip on film (COF) bonding. By using of an anisotropic conductive film to connect two different electronic components, it can provide an efficacy of vertical (in Z direction) electrical conduction and horizontal (in X and Y direction) insulation between electronic components at ultra-fine pitch, that a common electric connector cannot achieve without a short circuit.

Anisotropic conductive films in the t e of art mainly comprise a resin and conductive particles. In order to enhance the vertical (in Z direction) electrical conduction, larger conductive particles are applied or the amount of conductive particles is increased in conductive films. However, the approaches mentioned above may induce horizontal (in X and Y direction) electrical conduction during the bonding process between two electronic components so as to cause shortcuts. In addition, with the miniaturization of the IC bump pitches and the reduction of the bump space, it is more and more difficult to avoid the horizontal (in X and Y direction) electrical conduction in the anisotropic conductive films.

### SUMMARY OF THE INVENTION

For these reasons, the present invention provides a novel structure of an anisotropic conductive film. The anisotropic conductive film can effectively match the adhesive areas and pitches between the connected electronic components. Therefore, the novel anisotropic conductive film only needs less conductive particles and saves the cost. More particularly, the anisotropic conductive film of the present invention can avoid shortcuts occurring in horizontal (in X and Y direction) electrical conduction.

According to an aspect of the present invention, an anisotropic conductive film is provided. The anisotropic conductive film comprises a substrate, a plurality of insulating resin walls, and a conductive material. Each of the insulating resin walls is disposed on the substrate in parallel to each other. The conductive material is arranged between the insulating resin walls and the conductive material has conductivity along a direction parallel to the insulating resin walls.

According to another aspect of the present invention, the plurality of insulating resin walls are made of Ultra Violet (UV) curable resin or thermo curable resin. The material of the insulating resin wall is selected at least one from the group consisting of acrylic resin, silicone and polyurethane. The upper surface of the insulating resin walls is a flat plane, an arched surface or a plane with at least one inclined plane.

According to a yet another aspect of the present invention, the width of the insulating resin walls is in the range of 5 microns to 300 microns, the height of the insulating resin wails is in the range of 3 microns to 30 microns, the pitch between each insulating resin wall is in the range of 5 microns to 100 microns.

According to further another aspect of the present invention, the conductive materials is selected from the group consisting of a resin, conductive particles, conductive metal wires and conductive polymers.

According to further another aspect of the present invention, the conductive materials preferably comprises a resin and a plurality of conductive wires. The conductive wires are preferably silver wires.

According to further another aspect of the present invention, the substrate is a release film.

The above and other aspects of the invention will become better understood with regard to the following detailed description of the preferred but non-limiting embodiment(s). The following description is made with reference to the accompany drawings.

### BRIEF DESCRIPTION OF THE DRAWINGS

FIG. 1 shows a schematic diagram of an anisotropic film of the first embodiment of the present invention.

FIGS. 2A to 2D show schematic diagrams for a manufacturing method of an anisotropic conductive film of the first embodiment of the present invention.

FIG. 3 shows a schematic diagram of an anisotropic conductive film of the second embodiment of the present invention.

### DETAILED DESCRIPTION OF THE INVENTION

Various embodiments of the anisotropic conductive film are disclosed below for detailed descriptions of the invention. The embodiments are for exemplification purpose only, not for limiting the scope of protection of the invention.

### First Embodiment

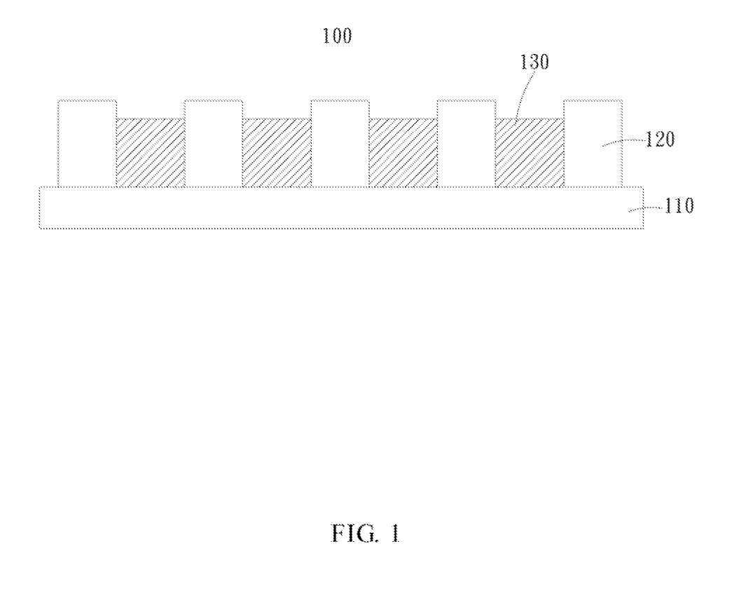

Referring to FIG. 1, a schematic diagram of an anisotropic film 100 of the first embodiment is shown. The anisotropic conductive film 100 comprises a substrate 110, a plurality of insulating resin walls 120, and the conductive materials 130. The substrate 110 is a transparent substrate, such as a release film.

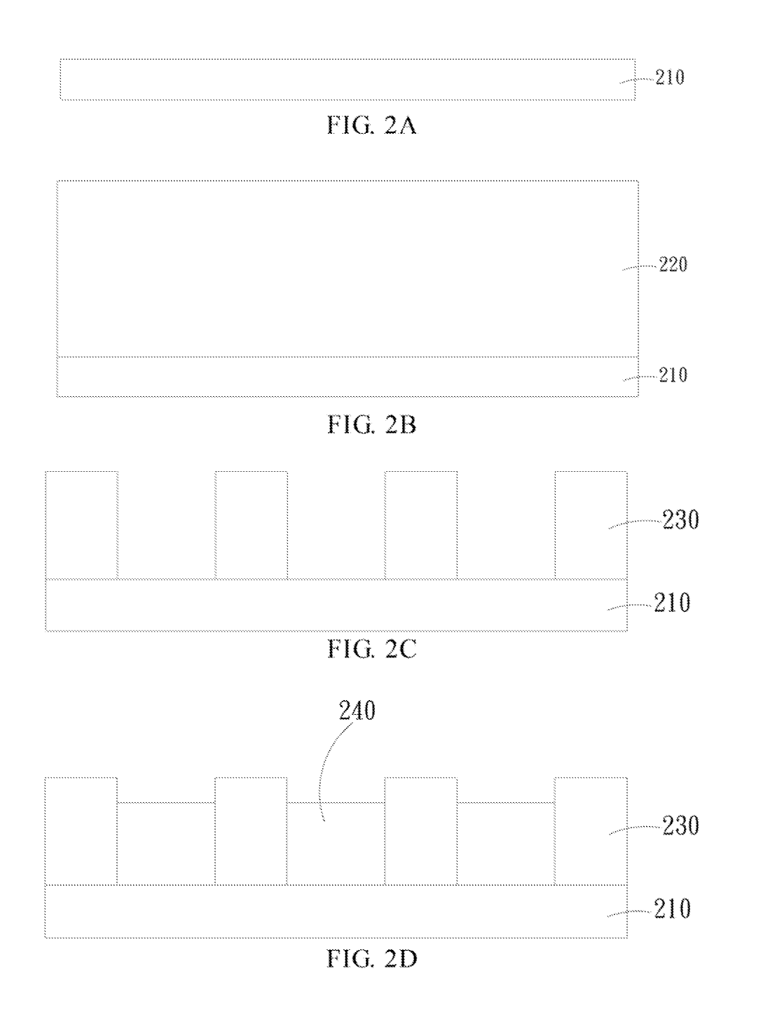

Referring to FIGS. 2A to 2D, a manufacturing method of an anisotropic conductive film 100 of the first embodiment of the present invention is shown as the schematic diagrams. FIGS. 2A to 2C are schematic diagrams for a manufacturing method of a plurality of insulating resin walls 120. A substrate 210 is provided as shown in FIG. 2A. Then as indicated in FIG. 2B, an insulated resin 220 is coated on the transparent substrate 210. The insulated resin 220 is coated by a process known to a skilled artisan, such as die coating or gravure coating. The insulating resin 220 is UV curable resin or thermo-curable resin, such as, for example, acrylic resin, silicone or polyurethane.

After the insulated resin 220 is coated, the insulated resin 220 is embossed by a mold with a predetermined pattern thereon to form a plurality of insulating resin walls 230 on the transparent substrate 210. Each of the insulating resin walls is disposed on the substrate in parallel to each other. The upper surface of the extending walls 230 can be a flat plane, an arched surface or a plane with at least one inclined plane. In a preferred embodiment of the invention, the upper surface of the insulating resin walls is a flat plane.

In another preferred embodiment of the invention, to match the adhesive areas of the connected electronic components, the width of the insulating resin walls is in the range of 5 microns to 300 microns, the height of the insulating resin walls is in the range of 3 microns to 30 microns, the pitch between every two of the insulating resin walls is in the range of 5 microns to 100 microns.

Finally, the conductive materials 240 is arranged between the insulating resin walls 230 to provide conductivity along a direction parallel to the insulating resin walls 230, as shown in FIG. 2D. The conductive material 240 is selected from the group consisting of a resin, conductive particles, conductive metal wires and conductive polymers. In a preferred embodiment of the invention, the conductive materials is consisted of a resin and conductive particles wherein the conductive particles are made of, for example, gold, silver, copper or nickel. In another preferred embodiment of the invention, the resin is selected from the group of an epoxy resin, a polyimide resin, a silicone resin, an acrylic resin, a polyester resin and a polysulfone resin.

For enhancing electrical conduction efficiency of he conductive materials arranged between the insulating resin walls, the particle size of conductive particles is in the range of 3 microns to 30 microns, preferably is in the range of 5 microns to 10 microns. The weight percent of conductive particles to a resin in the conductive materials 240 is preferred in the range of 5:95 to 30:70. In another preferred embodiment of the invention, the conductive particle is a hollow metal particle with a cavity formed therein, the cavity of the hollow metal particle can absorb an external pressure to prevent the connected electronic components from damage during the bonding process. The type, shape, particle size or amount of conductive particles mentioned above can be selected according to the requirements of the specific anisotropic conductive film by those with common knowledge in the art.

Besides, the height of the conductive materials arranged between the insulating resin walls is not higher than the insulating resin walls, or it can result in horizontal electrical conduction. In another preferred embodiment of the invention, the height of the conductive material is in the range of 5 microns to 10 microns.

### Second Embodiment

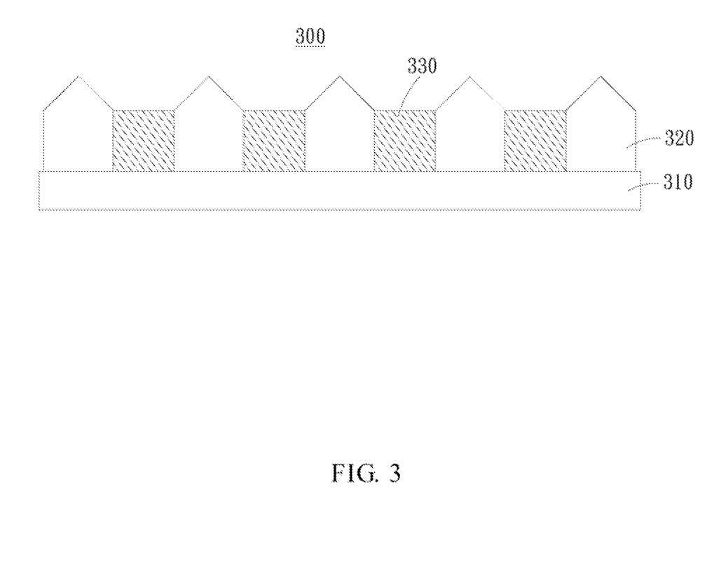

Referring to FIG. 3, an anisotropic conductive film 300 of the second embodiment is shown as a schematic diagram. The anisotropic conductive film 300 and the anisotropic conductive film 100 are generally similar, except that the upper surface of the insulating resin walls and the type of the conductive material. In the second embodiment of the present invention, the upper surface of the insulating resin walls is formed by two inclined planes to avoid the conductive material remaining thereon to cause horizontal (in X and Y direction) electrical conduction. The inclined angles of two inclined planes are preferred in the range of 60 degrees to 120 degrees. The upper surface of the insulating resin walls are not limited to the two inclined planes, the upper surface is also, for example, a flat plane, an arched surface or a plane with at least one inclined plane.

The conductive materials 330 in the second embodiment of the present invention are consisted of a resin and conductive metal wires. In order to enhance the vertical (in Z direction) electrical conduction, the diameter of conductive metal sires is in the range of 50 nanometers to 500 nanometers, the aspect ratio preferred ranges from 3 to 100, the weight percent of conductive metal wires to a resin is 0.5:99.5 to 10:90. The type and amount of conductive metal wires mentioned above are known to an artisan skilled in the art.

While the invention has been described by way of example(s) and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An anisotropic conductive film, co pr sing:
a substrate;
a plurality of insulating resin walls deposited in parallel on the substrate; and
a conductive material arranged between the insulating resin walls and having conductivity along a direction parallel to the insulating resin walls.

2. The anisotropic conductive film according to claim 1, the width of the insulating resin walls is in the range of 5 microns to 300 microns.

3. The anisotropic conductive film according to claim 1, the height of the insulating resin walls is in the range of 3 microns to 30 microns.

4. The anisotropic conductive film according to claim 1, the pitch between every two of the insulating resin wall is in the range of 5 microns to 100 microns.

5. The anisotropic conductive film according to claim 1, an upper surface structure of the insulating resin wails is a flat plane, an arched surface or a plane with at least one inclined plane.

6. The anisotropic conductive film according to claim 1, the conductive materials is selected from the group consisting of a resin, conductive particles, conductive metal wires and conductive polymers.

7. The anisotropic conductive film according to claim 1, the substrate is a releasing film.

8. The anisotropic conductive film according to claim 1, the insulating resin walls are made from a material at least one selected from the group consisting of acrylic resin, silicone and polyurethane.

9. The anisotropic conductive film according to claim 6, the particle size of the conductive particles is in the range of 3 microns to 30 microns.

10. The anisotropic conductive film according to claim 6, the diameter of the conductive metal wires is in the range of 50 nanometers to 500 nanometers and the aspect ratio is 3 to 100.
